(19) United States
(12) Patent Application Publication
(10) Pub. No.: US 2026/0193419 A1
(43) Pub. Date: Jul. 9, 2026

(54) RESIN COMPOSITION AND PREPREG AND METAL CLAD LAMINATE INCLUDING THE SAME

(71) Applicant: NAN YA PLASTICS CORPORATION, Taipei City (TW)

(72) Inventors: Ching-Yao Yuan, Taipei City (TW); Yi-Je Tsai, Taipei City (TW); Wei-Ru Huang, Taipei City (TW); Hung-Yi Chang, Taipei City (TW)

(73) Assignee: NAN YA PLASTICS CORPORATION, Taipei City (TW)

(21) Appl. No.: 19/064,697

(22) Filed: Feb. 27, 2025

(30) Foreign Application Priority Data
Jan. 9, 2025 (TW) 114100834

(51) Int. Cl. C08G 77/455; C08G 73/10; C08G 77/26; C08G 77/388

(52) U.S. Cl. CPC C08G 77/455; C08G 73/1032; C08G 77/26; C08G 77/388

(57) ABSTRACT

A resin composition includes a modified bismaleimide prepolymer. The modified bismaleimide prepolymer includes alternating hard and soft segments. The hard segment includes a bismaleimide monomer, and the soft segment includes a siloxane resin modified with an amino group at both ends.

### CROSS-REFERENCE TO RELATED APPLICATION

This application claims the priority benefit of Taiwan application serial no. 114100834, filed on Jan. 9, 2025. The entirety of the above-mentioned patent application is hereby incorporated by reference herein and made a part of this specification.

### BACKGROUND

### Technical Field

The present disclosure relates to a composition, and particularly relates to a resin composition and a prepreg and a metal clad laminate including the same.

### Description of Related Art

Bismaleimide resin, as a matrix resin for advanced composite materials, possesses excellent heat resistance and moisture resistance properties, and has been successfully applied in the field of high-performance copper-clad laminates. However, the dissipation factor (Df) of bismaleimide resin-based copper-clad laminates is not sufficiently low, which limits its application in the domain of high-end electronic products.

Furthermore, with the advancement of integrated circuit technology, the number and density of chips on copper foil substrates have correspondingly increased. Consequently, the requirements for low warpage and low thermal expansion characteristics of copper foil substrate materials have become increasingly stringent.

Based on the foregoing, to meet the demands of high-end electronic products, the development of a resin composition for the preparation of copper foil substrates with low dissipation factor and low coefficient of thermal expansion is an objective urgently sought by those skilled in the art.

### SUMMARY

The present disclosure provides a resin composition that possesses reduced dissipation factor and reduced coefficient of thermal expansion.

In the present disclosure, a resin composition includes a modified bismaleimide prepolymer. The modified bismaleimide prepolymer includes a hard segment and a soft segment arranged alternately. The hard segment includes a bismaleimide monomer, and the soft segment includes a siloxane resin modified with an amino group at both ends.

In an embodiment of the present disclosure, the molar ratio of the maleic anhydride groups in the bismaleimide monomer to the amino group in the siloxane resin modified with the amino group at both ends is 2:1.

In an embodiment of the present disclosure, the bismaleimide monomer possesses a structure represented by the following formula A.

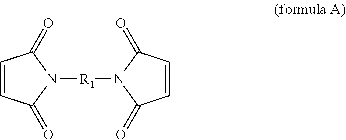

wherein R₁ represents a divalent aromatic group.

In an embodiment of the present disclosure, the siloxane resin modified with the amino group at both ends possesses a structure represented by the following formula B:

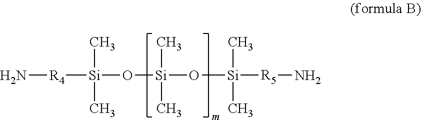

wherein R₄ and R₅ each independently represent C1 to C10 alkyl, m is an integer from 0 to 10.

In an embodiment of the present disclosure, the modified bismaleimide prepolymer possesses a structure represented by the following formula 1:

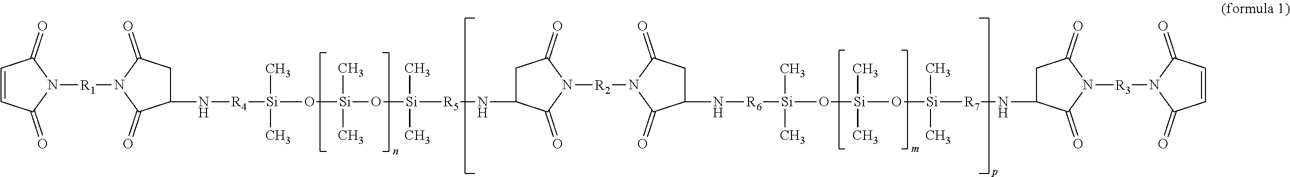

wherein,
R₁ to R₃ represent

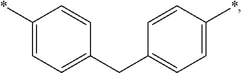

wherein * indicates the bonding position,
R₄ to R₇ each independently represent C1 to C10 alkyl, and
m, n, and p each independently represent an integer from 0 to 10.

In an embodiment of the present disclosure, the modified bismaleimide prepolymer has a number average molecular weight of 1,500 g/mol to 2,000 g/mol, and a weight average molecular weight of 8,000 g/mol to 22,000 g/mol.

In an embodiment of the present disclosure, based on the total weight of the resin composition, the resin composition includes: 5.0 wt % to 12.0 wt % of the modified bismaleimide prepolymer; 26 wt % to 33 wt % of bismaleimide resin; 4.0 wt % to 7.0 wt % of epoxy resin; 14 wt % to 15 wt % of curing agent; 0.01 wt % to 0.05 wt % of promoter; and 40 wt % to 45 wt % of inorganic filler.

The present disclosure further provides a prepreg, including the above-mentioned resin composition and a fibrous substrate.

The present disclosure further provides a metal clad laminate, including the above-mentioned prepreg and a metal foil.

In an example of the present disclosure, the metal clad laminate possesses a dissipation factor of 0.0069 or less and a coefficient of thermal expansion of 3.9 ppm/° C. or less.

Based on the above, the resin composition of the present disclosure, by using a modified bismaleimide prepolymer composed of alternately arranged bismaleimide monomer and siloxane resin modified with an amino group at both ends, may effectively reduce the dissipation factor and coefficient of thermal expansion of the metal clad laminate (for example, copper clad laminate).

### BRIEF DESCRIPTION OF THE DRAWINGS

FIG. 1 is a gel permeation chromatography (GPC) analysis spectrum according to an example of the present disclosure.

FIG. 2 is a GPC analysis spectrum according to another example of the present disclosure.

### DESCRIPTION OF THE EMBODIMENTS

The following are examples describing the content of the present disclosure in detail. The implementation details presented in the examples are for illustrative purposes and are not intended to limit the scope to be protected by the present disclosure. Any person skilled in the art may modify or vary these implementation details according to the needs of actual implementation.

Ranges in the embodiments may be expressed from “about” one specific value to “about” another specific value, or may be directly expressed as one specific value and/or to another specific value. When expressing the said range, another embodiment includes values from the one specific value and/or to another specific value. Similarly, when values are expressed as approximations by using the antecedent “about”, it will be understood that the specific value forms another embodiment. It will be further understood that the endpoints of each range are clearly related or unrelated to another endpoint.

In the text, non-limiting terms (such as: may, can, for example, or other similar expressions) represent non-essential or optional implementation, inclusion, addition, or presence.

Unless otherwise defined, all terms used herein (including technical and scientific terms) possess the same meanings as commonly understood by a person with ordinary knowledge in the field of technology to which this disclosure pertains. It will also be understood that terms (such as those defined in commonly used dictionaries) should be interpreted as having meanings consistent with their meaning in the context of the relevant art and should not be interpreted in an idealized or overly formal sense unless expressly so defined herein.

In the text, the term “divalent organic group” refers to an organic group with two bonding positions, and the “divalent organic group” may form two chemical bonds through these two bonding positions.

The term “amine equivalent” used in the text refers to the quotient of the molecular weight of the amine reactant divided by the number of active hydrogens it contains, with the unit of grams per mole (g/mol).

A resin composition in an embodiment of the present disclosure includes a modified bismaleimide prepolymer. In some embodiments, in addition to the modified bismaleimide prepolymer, the resin composition may further include a bismaleimide resin, an epoxy resin, a curing agent, a promoter, and an inorganic filler. The following will provide a detailed explanation of the various ingredients mentioned above.

### <Modified Bismaleimide Prepolymer>

According to an embodiment of the present disclosure, the modified bismaleimide prepolymer is synthesized with bismaleimide monomer as the hard segment and siloxane resin modified with an amino group at both ends as the soft segment, forming an orderly alternating modified bismaleimide prepolymer, such that the maleimide functional groups therein are orderly arranged, thereby reducing the polarity distribution of the modified bismaleimide prepolymer, which in turn lowers the electrical properties of modified bismaleimide prepolymer and reduce the coefficient of thermal expansion of the modified bismaleimide prepolymer.

In some embodiments, the bismaleimide monomer possesses a structure represented by the following formula A:

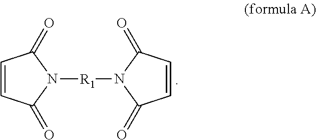

In formula A, R₁ may represent a divalent organic group, for example, a divalent aromatic group. For example, R₁ is

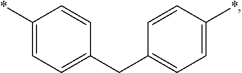

wherein * indicates the bonding position.

The siloxane resin modified with an amino group at both ends is a siloxane resin with two opposing ends modified by amino groups, which may also be called siloxane diamine. In some embodiments, the siloxane resin modified with an amino group at both ends possesses a structure represented by the following formula B:

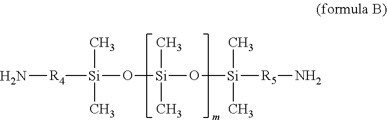

In formula B, R₄ and R₅ may each independently represent a C1 to C10 straight-chain alkyl, m may be an integer from 0 to 10. For example, R₄ and R₅ are each independently methyl, ethyl, propyl, n-butyl, n-pentyl, n-hexyl, n-heptyl, n-octyl, n-nonyl or n-decyl. In some embodiments, m is an integer from 1 to 5, for example, 2, 3 or 4.

In some embodiments, the modified bismaleimide prepolymer possesses a structure represented by the following formula 1:

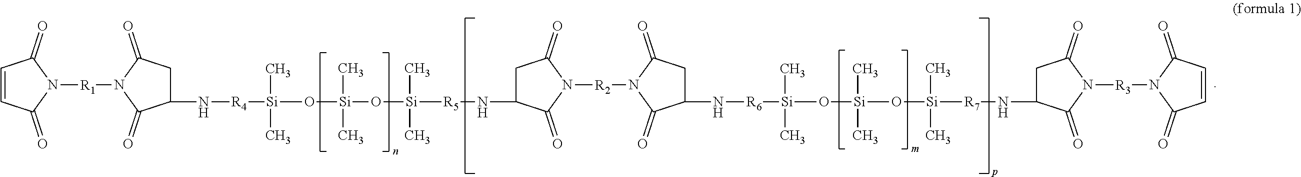

In formula 1, R₁ to R₃ may each independently represent a divalent organic group, for example, a divalent aromatic group. For example, R₁ to R₃ are

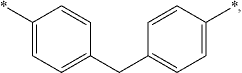

wherein * indicates the bonding position.

In formula 1, R₄ to R₇ may each independently represent a C1 to C10 straight-chain alkyl. For example, R₄ to R₇ are each independently methyl, ethyl, propyl, n-butyl, n-pentyl, n-hexyl, n-heptyl, n-octyl, n-nonyl or n-decyl. In some embodiments, R₄ to R₇ are all propyl.

In formula 1, m, n and p may each independently represent an integer from 0 to 10. In some examples, m, n and p are each independently an integer from 1 to 5, for example, m, n and p are each independently 2, 3 or 4.

In some embodiments, based on the total weight of the resin composition, the amount of modified bismaleimide prepolymer added is about 5.0 wt % to 12.0 wt %, for example, about 7.0 wt % or about 10.0 wt %. In some embodiments, the number average molecular weight of the modified bismaleimide prepolymer is about 1,500 g/mol to about 2,000 g/mol. In some embodiments, the weight average molecular weight of the modified bismaleimide prepolymer is about 8,000 g/mol to about 22,000 g/mol.

### <Method for Preparing Modified Bismaleimide Prepolymer>

First, the bismaleimide resin is dissolved in a solvent. For example, the bismaleimide resin is bis(4-maleimidophenyl)methane. In some embodiments, the bismaleimide resin is at least one or a combination of products BMI-1000, BMI-1000H, BMI-2300 and BMI-7000 provided by DAIWA FINE CHEMICALS (TAIWAN) CO., LTD., and products BMI-70 and BMI-80 provided by K⋅I Chemical Industry Co., LTD. in Japan. The solvent may be selected from, for example, propylene glycol monomethyl ether acetate. In some embodiments, the bismaleimide resin may be uniformly dispersed in the solvent by heating and stirring, wherein the bismaleimide resin may be heated to about 100° C. to about 120° C., for example, about 110° C., and stirring may continue for about 10 minutes to about 30 minutes, for example, about 15 minutes.

Next, siloxane resin modified with an amino group at both ends is added, and heated to about 100° C. to about 150° C., for example, about 120° C., and continuously stirred for reaction for about 2 hours to about 8 hours, for example, about 4 hours, to obtain a solution containing modified bismaleimide prepolymer. In some embodiments, the siloxane resin modified with an amino group at both ends includes siloxane diamine (amine equivalent of about 450 g/mol) with the product name BY16-853U provided by Dow Chemical Company, siloxane diamine (amine equivalent of about 220 g/mol) with the product name KF-8012 provided by Shin-Etsu Chemical Co., Ltd., or a combination of the above.

### <Bismaleimide Resin>

In some embodiments, the resin composition further includes bismaleimide resin, which is unmodified bismaleimide resin, different from the aforementioned modified bismaleimide prepolymer. In some embodiments, based on the total weight of the resin composition, the amount of bismaleimide resin added is about 26 wt % to about 33 wt %, for example, about 28 wt % or about 31 wt %. In some embodiments, the bismaleimide resin includes at least one or a combination of BMI-1000, BMI-1000H, BMI-2300, BMI-7000, BMI-70 and BMI-80.

### <Epoxy Resin>

The epoxy resin may be selected from, for example, naphthalene-based epoxy resin. The epoxy resin may be, but is not limited to, epoxy resins manufactured by DIC Corporation (abbreviated as DIC) with model numbers 7050, HP4710, HP-4700, HP-6000, HP-7200, or N-695; epoxy resins manufactured by Nippon Kayaku Co., Ltd. with model numbers NC-7300, NC7000L, NC3000, or NC3500; epoxy resins manufactured by Nippon Steel Chemical Co., Ltd. with model numbers ESN475V or ESN485; epoxy resins manufactured by Mitsubishi Chemical Corporation with model numbers YX4000 or YL7760, or epoxy resins manufactured by Nan Ya Plastics Corporation with model numbers NPES-903, NPEL-128E, or NPEL-170. The epoxy resin may be, for example, one or more of the above materials. In some examples, based on the total weight of the resin composition, the amount of epoxy resin added is about 4.0 wt % to about 7.0 wt %, for example, about 5.8 wt %.

### <Curing Agent>

The curing agent may include, for example, benzoxazine-based curing agents, 1,3,5-triallyl cyanurate (TAC), triallyl isocyanurate (TAIC; CAS number 1025-15-6), trimethallyl isocyanurate (TMAIC), diallyl phthalate, divinylbenzene, 1,2,4-triallyl trimellitate, and other suitable crosslinking curing agents. The above materials may be used alone or in combination. In some embodiments, the curing agent is KB-610F, a product provided by Kumho Company. In some embodiments, based on the total weight of the resin composition, the amount of curing agent added may be about 14 wt % to about 15 wt %, for example, about 14.7 wt %.

### <Promoter>

To enhance system reactivity, the resin composition may further include a promoter, for example, an imidazole-based promoter. For example, the promoter may be 2-phenyl-4-methyl-5-hydroxymethylimidazole, but the present disclosure is not limited to the example mentioned above. In some embodiments, the promoter includes a product named 2P4MHZ-PW provided by Shikoku Chemicals Corporation. In some embodiments, based on the total weight of the resin composition, the amount of promoter added may be about 0.01 wt % to about 0.05 wt %, for example, about 0.03 wt %.

### <Inorganic Filler>

In some embodiments, the resin composition may further include an inorganic filler. For example, the inorganic filler may be: silicon dioxide (SiO₂), titanium dioxide, aluminum hydroxide, aluminum oxide, magnesium hydroxide, magnesium oxide, calcium carbonate, boron oxide, calcium oxide, strontium titanate, barium titanate, calcium titanate, magnesium titanate, boron nitride, aluminum nitride, silicon carbide, cerium dioxide, or combinations thereof. In some embodiments, the silicon dioxide used as an inorganic filler additive may include spherical SiO₂. Spherical SiO₂ may be prepared using a synthetic method to reduce electrical properties and maintain flowability and gel filling properties. The average particle size D50 of the inorganic filler may be about 2.0 μm to about 3.0 μm. Based on the total weight of the resin composition, the amount of inorganic filler added may be about 40 wt % to about 45 wt %, for example, about 41 wt %. In some embodiments, when the non-volatile ingredients in the resin composition are set to 100 wt %, the content of inorganic filler may be about 70 wt % to about 80 wt %. In some examples, the inorganic filler is synthetic SiO₂ purchased from Sanshi Century Company with the model number EQH1003-SKD.

It should be noted that the resin composition of the present disclosure may be processed into a prepreg and a metal clad laminate (for example, a copper clad laminate (CCL)) according to actual design requirements, and the prepreg and metal clad laminate made using the resin composition of the present disclosure may possess reduced coefficient of thermal expansion (CTE) and reduced dissipation factor (Df). In some embodiments, the CTE of the metal clad laminate (or prepreg) made from the resin composition may be about 4.0 ppm/° C. or less, for example, about 3.9 ppm/° C. or less. In some embodiments, the Df of the metal clad laminate (or prepreg) made from the resin composition may be less than about 0.0070, for example, less than about 0.0069, for example, about 0.0068.

In some embodiments, the dielectric constant (Dk) of the metal clad laminate (or prepreg) made from the resin composition is between about 3.70 and about 3.75, for example, about 3.71 or about 3.74. In some embodiments, the glass transition temperature (Tg) of the metal clad laminate (or prepreg) made from the resin composition may be up to 318° C. or above, and may even reach about 322° C. In some embodiments, the peel strength of the metal clad laminate (or prepreg) made from the resin composition may even be up to about 4.66 lb/in. In some embodiments, the water absorption of the metal clad laminate (or prepreg) made from the resin composition is about 0.45 wt % or less, and may even reach about 0.31 wt % or less, after heating for 120 minutes in a pressure cooker at 120° C. and 2 atm.

The following experimental examples are used to explain in detail the aforementioned resin composition of the present disclosure. However, the experimental examples described below are not intended to limit the present disclosure.

### Experimental Examples

To demonstrate that the resin composition provided by the present disclosure may effectively reduce the Df and CTE of the metal clad laminate, the following experimental examples are provided for further explanation.

### <Synthesis of Modified Bismaleimide Prepolymer>

The following describes synthesis examples 1 to 2 of modified bismaleimide prepolymers.

### Synthesis Example 1

50.0 g of bis(4-maleimidophenyl)methane (molecular weight of 358 g/mol) and 117.8 g of propylene glycol monomethyl ether acetate (as solvent) were added to a round bottom flask, heated to about 110° C. and stirred for 15 minutes to allow the bis(4-maleimidophenyl)methane to disperse more uniformly in the propylene glycol monomethyl ether acetate. Then, 62.8 g of siloxane diamine with an amine equivalent of 450 g/mol was added, and the temperature was raised to about 120° C. and stirred for 4 hours to obtain the solution of the modified prepolymer of synthesis example 1.

By calculation, in the modified prepolymer of synthesis example 1, the molar ratio of maleic anhydride groups in the bismaleimide monomer to the amino group in the siloxane resin modified with an amino group at both ends is 2*50/358:62.8/450=2:1.

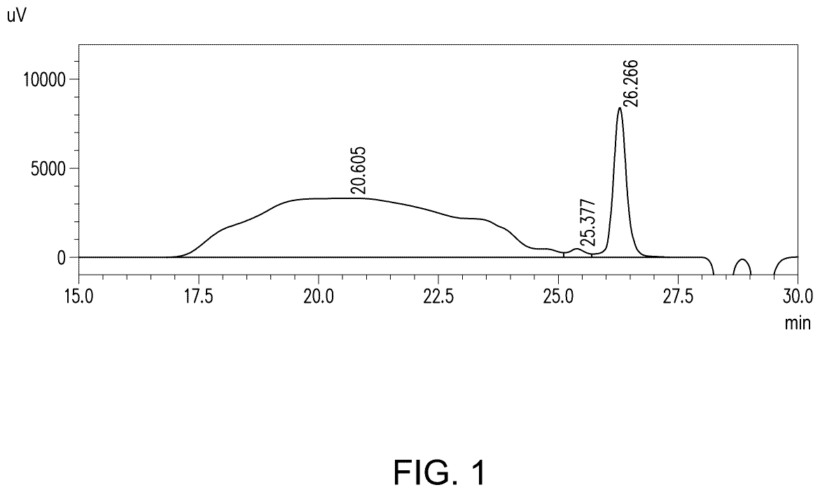

The solution of the modified prepolymer from synthesis example 1 was analyzed by Gel Permeation Chromatography (GPC), resulting in the GPC analysis spectrum shown in FIG. 1, where the horizontal axis unit is minutes (min). The number average molecular weight (Mn) was measured to be 1,614, the weight average molecular weight (Mw) was 9,446, and the ratio of weight average molecular weight to number average molecular weight was about 5.85. The number average molecular weight and weight average molecular weight may be measured by a gel permeation chromatograph (GPC), which may be calibrated using polystyrene (PS) with standard molecular weights, set at a flow rate of about 1.0 mL/min, and using tetrahydrofuran (THF) as the mobile phase.

The modified prepolymer of synthesis example 1 may include the modified bismaleimide prepolymer represented by the following formula 1:

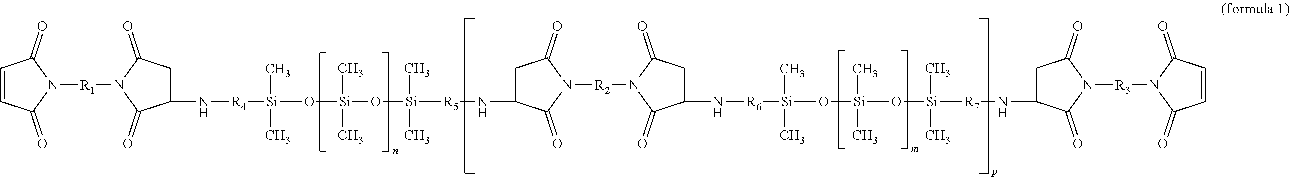

wherein R₁ to R₃ represent

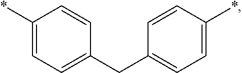

wherein * indicates the bonding position, R₄ to R₇ are C3 alkyl, m is 3, n is 3, and p is 2.

### Synthesis Example 2

20.0 g of bis(4-maleimidophenyl)methane and 142.8 g of propylene glycol monomethyl ether acetate were added to a round-bottom flask, heated to about 110° C., and stirred for 15 minutes. Then, 122.8 g of siloxane diamine with an amine equivalent of 2,200 g/mol was added, and the temperature was raised to about 120° C. The mixture was stirred continuously for 4 hours to obtain the modified prepolymer solution of synthesis example 2.

By calculation, in the modified prepolymer of synthesis example 2, the molar ratio of maleic anhydride groups in the bismaleimide monomer to the amino group in the siloxane resin modified with an amino group at both ends is 2*20/358:122.8/2200=2:1.

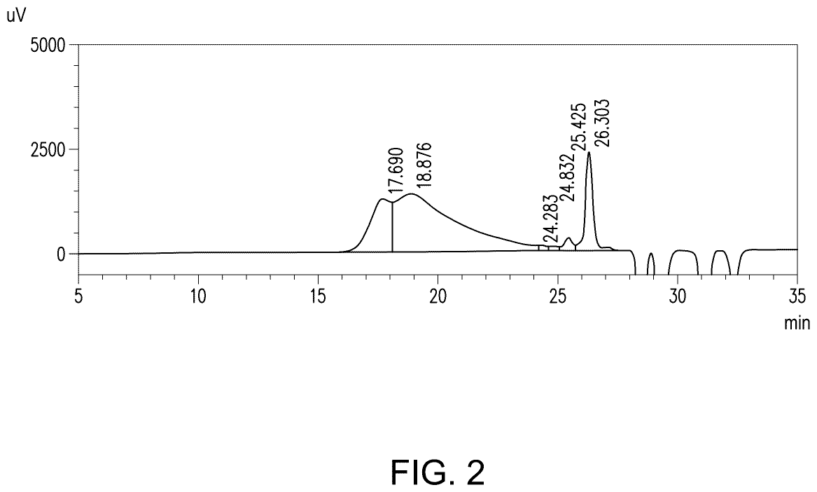

The solution of the modified prepolymer from synthesis example 2 was subjected to GPC analysis, resulting in the GPC chromatogram shown in FIG. 2. The analysis revealed a number average molecular weight of approximately 1,835, a weight average molecular weight of approximately 20,378, and a ratio of weight average molecular weight to number average molecular weight of about 11.1.

The modified prepolymer of synthesis example 2 may include the modified bismaleimide prepolymer represented by formula 1 above, wherein R₁ to R₃ represent

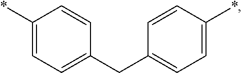

wherein * indicates the bonding position, R₄ to R₇ are C3 alkyl, m is 5, n is 5, and p is 4.

### <Manufacture of Metal Clad Laminate>

An example of the manufacturing method for a metal clad laminate is described as follows. According to the formulation composition in Table 1 below (unit: grams), the resin composition is dissolved in an appropriate solvent and mixed to prepare a resin varnish, which is then used to produce a metal clad laminate, such as a copper foil substrate, by known methods. In some embodiments, the aforementioned solvent may include, but is not limited to: toluene, methyl isobutyl ketone (MIBK), methyl ethyl ketone (MEK), dimethylacetamide (DMAC), dimethylformamide (DMF), propylene glycol monomethyl ether (PM), or a co-solvent including the above.

The aforementioned known method for preparing a metal clad laminate may include the following steps: impregnating a fibrous substrate (for example, glass fiber cloth with model number 2116 purchased from Nan Ya Plastics Corporation) in the above-mentioned resin varnish at room temperature, then drying for several minutes under conditions of about 170° C. (impregnation machine temperature). By adjusting and controlling the drying time, a dried prepreg is obtained. Subsequently, 8 layers of prepregs are stacked between two metal foils (for example, 35 μm thick copper foils). Under conditions such as a pressure of 25 kg/cm² and a temperature of 85° C., the stack is maintained at a constant temperature for 20 minutes, then heated to 250° C. at a heating rate of 3° C./min, and maintained at a constant temperature for 120 minutes. After that, the stack is slowly cooled to 130° C. to obtain a metal clad laminate (for example, a copper foil substrate) with a thickness of about 0.8 mm. Thereafter, various properties of the metal clad laminate are evaluated.

### <Evaluation Method>

The metal clad laminates (for example, copper foil substrate) produced from each example and comparative example were evaluated according to the following methods, with results listed in Table 1.

a. Glass Transition Temperature (Tg)

Testing was conducted using a dynamic mechanical analyzer (DMA).

b. Coefficient of Thermal Expansion (CTE)

Testing was conducted using a thermomechanical analyzer (TMA) according to the IPC TM-650 2.4.24 standard.

c. Peeling Strength

Testing was conducted using a universal tensile machine according to the IPC TM-650 2.4.8 standard.

d. Water Absorption Rate (%)

A 5 cm×5 cm square test piece was placed in an oven at about 105° C. for an appropriate measurement time (for example, about 2 hours), and then placed in a pressure cooker. The environmental conditions inside the pressure cooker were approximately 2 atm×120° C. After about 120 minutes in the pressure cooker, the water absorption rate was calculated as follows: (weight difference of the test piece before and after pressure cooking÷initial weight of the test piece)×100%.

e. Heat Resistance

The test sample was heated in a pressure cooker at a temperature of 120° C. and a pressure of 2 atm for 120 minutes, then immersed in a solder bath at 288±5° C., and the time required for delamination was recorded. A delamination time exceeding 10 min is indicated as “OK”, while a delamination time less than 10 min is indicated as “NG”.

f. Dielectric Constant (Dk)

The test method involved preparing a square test piece of approximately 5 cm×5 cm from the copper foil substrate with the copper foil removed. The test piece was dried in an oven at about 105° C. for about 2 hours, and its thickness was measured using a thickness gauge. The test piece was then clamped into an impedance analyzer (Agilent E4991A), and the average value of the dielectric constant Dk was obtained from three measurement points.

g. Dissipation Factor (Df)

The test method involved preparing a square test piece of approximately 5 cm×5 cm from the copper foil substrate with the copper foil removed. The test piece was dried in an oven at about 105° C. for about 2 hours, and its thickness was measured using a thickness gauge. The test piece was then clamped into an impedance analyzer (Agilent E4991A), and the average value of the dissipation factor Df was obtained from three measurement points.

### <Evaluation Results>

TABLE 1
Formulation Compositions and Evaluation Results of Examples and Comparative Examples

| | | | | | Comparative |
|---|---|---|---|---|---|
| Resin composition | | | Example 1 | Example 2 | example |
| Ingredients | Epoxy resin | NC-7300 | 5.88 | 5.88 | 5.88 |
| of | BMI resin | 50P | 20.58 | 20.58 | 20.58 |
| formulation | | BMI-1000 | 7.08 | 10.8 | 11.76 |
| | Modified | Synthesize | 10.56 | — | — |
| | prepolymer | Example 1 | | | |
| | | Synthesize | — | 6.84 | — |
| | | example 2 | | | |
| | Siloxane resin | FZ-3736 | — | — | 5.88 |
| | Curing agent | KB-610F | 14.7 | 14.7 | 14.7 |
| | Promoter | 2P4MHZ-PW | 0.03 | 0.03 | 0.03 |
| | Inorganic | EQH1003-SKD | 41.17 | 41.17 | 41.17 |
| | filler | | | | |

| | | | | |
|---|---|---|---|---|
| Evaluation | Tg (° C.) | 318 | 322 | 320 |
| result | CTE (ppm/° C.) | 3.83 | 3.67 | 4.22 |
| | Peel strength (lb/in) | 2.05 | 4.66 | 3.54 |
| | Water absorption rate (%) | 0.45% | 0.31% | 0.52% |
| | Heat resistance (@PCT 2 hr, | OK | OK | OK |
| | 288° C.) | | | |
| | Dk (10 GHz) | 3.71 | 3.74 | 3.72 |
| | Df (10 GHz) | 0.00676 | 0.00687 | 0.00931 |

### <Formulation Information in Table 1>

In the comparative example, example 1, and example 2, the epoxy resin used was the NC-7300 series resin provided by Nippon Kayaku Co., Ltd.

In the comparative example, example 1, and example 2, the bismaleimide (BMI) resin used was a resin with product name BMI-1000 provided by Daiwa Kasei and a resin with product name BMI-50P provided by KI Chemical Co., Ltd. in Japan.

In example 1 and example 2, the modified prepolymers used were the prepolymers prepared in the aforementioned synthesis example 1 and synthesis example 2, respectively.

In the comparative example, the siloxane resin used was a resin with product name FZ-3736 provided by Dow Chemical Company.

In the comparative example, example 1, and example 2, the curing agent used was a curing agent with product name KB-610F provided by Kuhmichel Company.

In the comparative example, example 1, and example 2, the promoter used was a promoter with product name 2P4MHZ-PW provided by Shikoku Chemical Industry Co., Ltd. in Japan, which possesses the structure represented by the following formula 2.

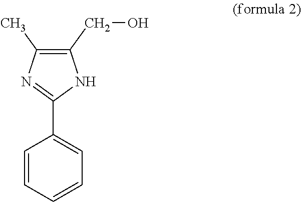

In the comparative example, example 1, and example 2, the inorganic filler used was a filler with product name EQH1003-SKD provided by Sanshiki Company.

From the experimental results in Table 1, it may be known that compared to the comparative example which does not use the modified bismaleimide prepolymer of the present disclosure, example 1 using the prepolymer of synthesis example 1 and example 2 using the prepolymer of synthesis example 2 both may possess a Df less than 0.0069 and a CTE less than 3.9 ppm/° C., and their Dk, Tg, peel strength, water absorption rate, and heat resistance all meet the requirements.

In summary, the resin composition of the present disclosure, by using a modified bismaleimide prepolymer composed of alternately arranged bismaleimide monomer and siloxane resin modified with an amino group at both ends, may effectively reduce the dissipation factor and coefficient of thermal expansion of the metal clad laminate.

### INDUSTRIAL APPLICABILITY

The resin composition of the present disclosure may be directly or indirectly applied to copper foil substrates, and may be further processed into other consumer, industrial, or suitable electronic components or electronic products (for example: circuit boards).

Although the present disclosure has been disclosed by the above embodiments, it is not intended to limit the present disclosure. Any person skilled in the art may make some modifications and refinements without departing from the spirit and scope of the present disclosure. Therefore, the scope to be protected by the present disclosure should be defined by the appended claims.

What is claimed is:

1. A resin composition, comprising:
a modified bismaleimide prepolymer, comprising a hard segment and a soft segment arranged alternately, wherein:
the hard segment comprises a bismaleimide monomer, and
the soft segment comprises a siloxane resin modified with an amino group at both ends.

2. The resin composition according to claim 1, wherein a molar ratio of maleic anhydride groups in the bismaleimide monomer to the amino group in the siloxane resin modified with the amino group at both ends is 2:1.

3. The resin composition according to claim 1, wherein the bismaleimide monomer possesses a structure represented by the following formula A: 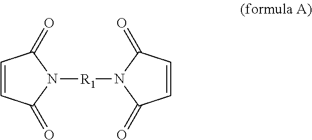
wherein R₁ represents a divalent aromatic group.

4. The resin composition according to claim 1, wherein the siloxane resin modified with the amino group at both ends possesses a structure represented by the following formula B: 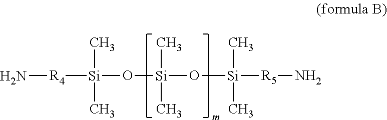
wherein R₄ and R₅ each independently represent C1 to C10 alkyl, m is an integer from 0 to 10.

5. The resin composition according to claim 1, wherein the modified bismaleimide prepolymer possesses a structure represented by the following formula 1: 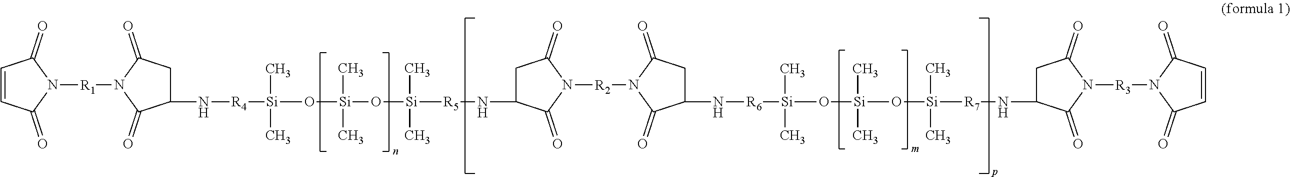
wherein,
R₁ to R₃ represent 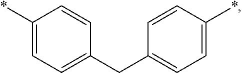
wherein * indicates a bonding position,
R₄ to R₇ each independently represent C1 to C10 alkyl, and
m, n, and p each independently represent an integer from 0 to 10.

6. The resin composition according to claim 1, wherein the modified bismaleimide prepolymer has a number average molecular weight of 1,500 g/mol to 2,000 g/mol, and a weight average molecular weight of 8,000 g/mol to 22,000 g/mol.

7. The resin composition according to claim 1, wherein based on a total weight of the resin composition, the resin composition comprises:
5.0 wt % to 12.0 wt % of the modified bismaleimide prepolymer;
26 wt % to 33 wt % of a bismaleimide resin;
4.0 wt % to 7.0 wt % of an epoxy resin;
14 wt % to 15 wt % of a curing agent;
0.01 wt % to 0.05 wt % of a promoter; and
40 wt % to 45 wt % of an inorganic filler.

8. A prepreg, comprising the resin composition according to claim 1 and a fibrous substrate.

9. A metal clad laminate, comprising the prepreg according to claim 8 and a metal foil.

10. The metal clad laminate according to claim 9, wherein the metal clad laminate possesses a dissipation factor of 0.0069 or less and a coefficient of thermal expansion of 3.9 ppm/° C. or less.
